(19) United States
(12) Patent Application Publication
(10) Pub. No.: US 2012/0012175 A1
(43) Pub. Date: Jan. 19, 2012

(54) SOLAR CELL AND MANUFACTURING METHOD THEREOF

(75) Inventors: Kyoung Jin Seo, Suwon-si (KR); Meemongkolkiat Vichai, Suwon-si (KR)

(73) Assignee: SAMSUNG ELECTRONICS CO., LTD., Suwon-si (KR)

(21) Appl. No.: 13/094,940

(22) Filed: Apr. 27, 2011

(30) Foreign Application Priority Data
Jul. 19, 2010 (KR) 10-2010-0069635

(51) Int. Cl. H01L 31/02; H01L 31/0232

(52) U.S. Cl. 136/256; 438/72; 257/E31.127

(57) ABSTRACT

A solar cell includes a base layer including a first conductive type impurity element, an upper surface, and a lower surface opposing the upper surface, an emitter layer disposed on the upper surface of the base layer and including a second conductive type impurity element opposing the first conductive type impurity element, a front electrode connected to the emitter layer, a first passivation layer disposed on the lower surface of the base layer, and a rear electrode disposed on the first passivation layer and connected to the base layer. The first passivation layer includes a silicon nitride group compound, and a refractive index of the silicon nitride group compound is less than about 1.96.

This application claims priority to Korean Patent Application No. 10-2010-0069635 filed on Jul. 19, 2010, and all the benefits accruing therefrom under 35 U.S.C. §119, the entire contents of which are incorporated herein by reference.

### BACKGROUND OF THE INVENTION

(a) Field of the Invention

The invention relates to a solar cell and a manufacturing method thereof.

(b) Description of the Related Art

A solar cell is a device that converts solar light energy into electrical energy by using a photoelectric effect.

It is important to develop clean energy or next-generation energy that can replace fossil fuel energy that causes a greenhouse gas effect from carbon dioxide (CO₂) gas discharge and atomic power that pollutes the environment such as through atmospheric pollution by radioactive waste.

A solar cell that uses silicon as a light absorption layer may be classified as a crystalline substrate (e.g., wafer) type of solar cell, and a thin film type (e.g., amorphous, polycrystalline) of solar cell.

In addition, a compound thin film solar cell that uses CuInGaSe2 (“CIGS”) or cadmium telluride (CdTe), a Group III-V solar cell, a dye sensitive solar cell, and an organic solar cell may be representative of solar cells.

The basic structure of a solar cell has a conjunction structure of a P-type semiconductor and an N-type semiconductor, such as a diode, and if light is incident to the solar cell, electrons having a negative (−) charge and holes that have a positive (+) charge caused by the removal of electrons are generated by interaction of light and a material that constitutes the semiconductor of the solar cell, such that a current flows while they move.

This is called a photovoltaic effect. In the P-type and N-type semiconductors that constitute the solar cell, the electrons are drawn to the N-type semiconductor and the holes are drawn to the P-type semiconductor, such that the electrons and the holes move to the electrodes that are connected to the N-type semiconductor and P-type semiconductor. If the electrodes are connected to wires, a current flows, thereby obtaining electrical power.

To reduce the manufacturing cost of the solar cell, research to reduce the thickness of the silicon wafer as a raw material has been undertaken. However when the thickness of the silicon wafer is reduced, the photo-efficiency of the solar cell may be deteriorated.

Accordingly, research on a rear passivation layer to realize a highly efficiency solar cell has progressed.

### BRIEF SUMMARY OF THE INVENTION

The invention provides a solar cell and a manufacturing method thereof that are capable of simplifying a manufacturing process of a rear passivation layer, realizing a high efficiency solar cell, and ensuring long reliability.

An exemplary embodiment of a solar cell includes a base layer including a first conductive type impurity element, an upper surface, and a lower surface opposing the upper surface, an emitter layer on the upper surface of the base layer and including a second conductive type impurity element opposing the first conductive type impurity element, a front electrode connected to the emitter layer, a first passivation layer on the lower surface of the base layer, and a rear electrode on the first passivation layer and connected to the base layer. The first passivation layer includes a silicon nitride group compound, and a refractive index of the silicon nitride group compound is equal to or less than about 1.96.

The refractive index of the silicon nitride group compound may be in a range of about 1.8 to about 1.96.

A light absorption coefficient of the first passivation layer may be equal to or less than about 0.01.

A second passivation layer between the lower surface of the base layer and the first passivation layer may be further included in the solar cell.

The second passivation layer may include aluminum oxide (Al₂O₃).

A reflection prevention layer on the emitter layer may be further included in the solar cell.

The front electrode may penetrate the reflection prevention layer and may be connected to the emitter layer.

A portion of the rear electrode may penetrate the first passivation layer and may be connected to the base layer.

A rear electric field layer under the base layer may be further included.

An exemplary embodiment of a manufacturing method of a solar cell includes forming a base layer including a first conductive type impurity element, an upper surface, and a lower surface opposing the upper surface, forming an emitter layer on the upper surface of the base layer and including a second conductive type impurity element opposing the first conductive type impurity element, forming a first passivation layer on the lower surface of the base layer, forming a second passivation layer on the first passivation layer, forming a front electrode connected to the emitter layer, and forming a rear electrode disposed on the second passivation layer and connected to the base layer. The second passivation layer includes a silicon nitride group compound (SiNx), and a refractive index of the silicon nitride group compound is equal to or less than about 1.96.

The refractive index of the silicon nitride group compound may be in a range of about 1.8 to about 1.96.

A light absorption coefficient of the second passivation layer may be equal to or less than about 0.01.

Forming a reflection prevention layer on the emitter layer may be further included in the method of forming a solar cell.

The first passivation layer may be formed of aluminum oxide (Al₂O₃).

The second passivation layer may be formed through plasma-enhanced chemical vapor deposition (“PECVD”).

The silicon nitride group compound of the second passivation layer may be formed by using a raw gas including silane (SiH₄) or ammonia (NH₃).

The raw gas for the formation of the silicon nitride group compound further may include nitrogen (N₂).

The forming of the second passivation layer may include a process condition in which gas flows of the silane (SiH₄), the ammonia (NH₃), and the nitrogen (N₂) are respectively 1000 standard cubic centimeters (sccm), 15,000 sccm, and 18,000 sccm.

According to an exemplary embodiment of the invention, a rear passivation layer having a low refractive index and a low light absorption coefficient is formed such that a high efficiency solar cell may be realized, and a solar cell capable of ensuring reliability for a long time may be manufactured.

Also, a high efficiency solar cell is realized while forming a rear passivation layer of a single layer such that the manufacturing process may be simplified and the cost may be reduced.

### BRIEF DESCRIPTION OF THE DRAWINGS

The above and other features of this disclosure will become more apparent by describing in further detail exemplary embodiments thereof with reference to the accompanying drawings, in which:

FIG. 1 is a cross-sectional view of an exemplary embodiment of a solar cell, according to the invention.

FIG. 2 is an enlarged view showing portion S of FIG. 1.

FIG. 3 is a graph showing a Fourier-Transform Infrared (“FT-IR”) analysis result for an Exemplary Example of a solar cell of the invention and a Comparative Example.

FIG. 4 is a graph showing leakage current of the Exemplary Example of the solar cell according to the invention and the Comparative Example.

FIG. 5 and FIG. 6 are graphs showing a measured open circuit voltage of Experimental embodiments of a solar cell according to the invention before forming an electrode, compared with Comparative Examples.

FIG. 7 is a graph showing a measured open circuit voltage and a fill factor of an Exemplary embodiment of a solar cell according to the invention after forming an electrode, compared with a Comparative Example.

FIG. 8 is a graph showing reliability of an Exemplary embodiment of a solar cell according to the invention, compared with Comparative Examples.

### DETAILED DESCRIPTION OF THE INVENTION

The invention is described more fully hereinafter with reference to the accompanying drawings, in which exemplary embodiments of the invention are shown. This invention may, however, be embodied in many different forms and should not be construed as limited to the exemplary embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity.

It will be understood that when an element or layer is referred to as being “on” or “connected to” another element or layer, the element or layer can be directly on or connected to another element or layer or intervening elements or layers. In contrast, when an element is referred to as being “directly on” or “directly connected to” another element or layer, there are no intervening elements or layers present. As used herein, connected may refer to elements being physically and/or electrically connected to each other.

Like numbers refer to like elements throughout. As used herein, the term “and/or” includes any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the invention.

Spatially relative terms, such as “lower,” “upper” and the like, may be used herein for ease of description to describe the relationship of one element or feature to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “lower” relative to other elements or features would then be oriented “upper” relative to the other elements or features. Thus, the exemplary term “lower” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

All methods described herein can be performed in a suitable order unless otherwise indicated herein or otherwise clearly contradicted by context. The use of any and all examples, or exemplary language (e.g., “such as”), is intended merely to better illustrate the invention and does not pose a limitation on the scope of the invention unless otherwise claimed. No language in the specification should be construed as indicating any non-claimed element as essential to the practice of the invention as used herein.

Hereinafter, the invention will be described in detail with reference to the accompanying drawings.

An exemplary embodiment of the invention will hereinafter be described in detail with reference to the accompanying drawings.

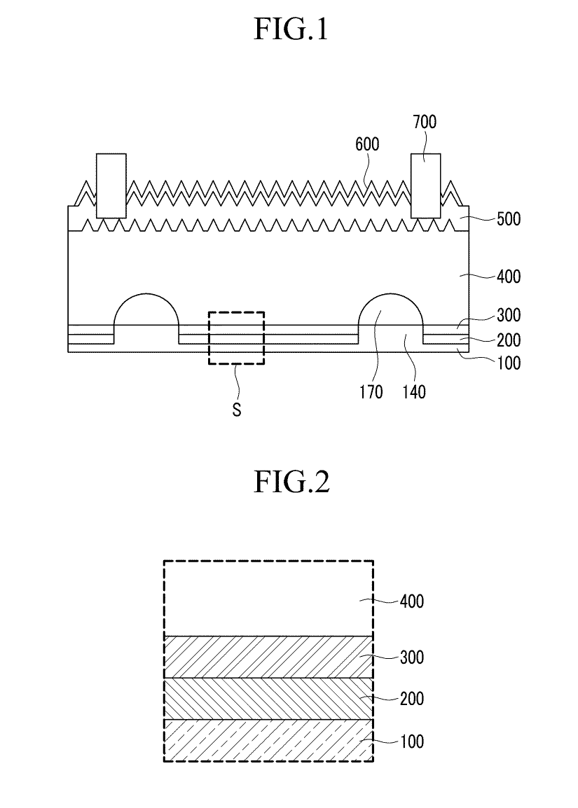

FIG. 1 is a cross-sectional view of an exemplary embodiment of a solar cell, according to the invention.

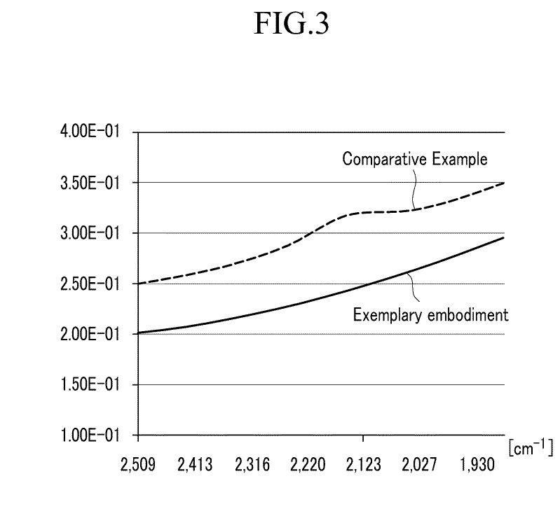

FIG. 2 is an enlarged view showing a portion of FIG. 1.

Referring to FIG. 1 and FIG. 2, an emitter layer 500 is on a base layer 400. The base layer 400 includes a first conductive type of impurity element (e.g., dopant). The emitter layer 500 includes a second conductive type of impurity element (e.g., dopant) opposite to the first conductive type of impurity element. The base layer 400 may include a P-type silicon substrate or an N-type silicon substrate. Conversely, the emitter layer 500 includes the N-type dopant or the P-type dopant, respectively.

In one exemplary embodiment, the P-type silicon substrate of the base layer 400 is doped with the first conductive type of impurity element of International Union of Pure and Applied Chemistry (IUPAC) Group III (or Group 13) elements, such as boron (B), gallium (Ga), and indium (In).

When the silicon substrate of the base layer 400 is a P-type, the emitter layer 500 is doped with the second conductive type of impurity element of IUPAC Group V (or Group 15) elements, such as phosphorus (P), arsenic (As), and antimony (Sb), or an N-type dopant. As used herein, the P-type dopants are considered “opposite” of the N-type dopants, for example, with respect to the IUPAC Group IV elements.

Here, a P-N junction is formed between the base layer 400 and the emitter layer 500.

A first passivation layer 200 is positioned on a lower surface of the base layer 400.

The first passivation layer 200 is formed of a compound of a silicon nitride group.

According to an exemplary embodiment of the invention, a second passivation layer 300 may be directly between the first passivation layer 200 and the base layer 400.

The second passivation layer 300 may include aluminum oxide (Al₂O₃).

When the base layer 400 is the P-type silicon substrate, the second passivation layer 300 reflects minority carriers generated by photo-energy as a fixed charge, and guides the minority carriers to a front electrode 700 such that a short circuit current may be increased, thereby increasing the solar cell efficiency.

When the second passivation layer 300 is a thin film, degradation of the film characteristics occurs by time and environmental effects.

In the exemplary embodiment of the invention, the first passivation layer 200 has a function of compensating this deterioration when the second passivation layer 300 is a thin film.

A rear electrode layer 100 is positioned directly on the first passivation layer 200.

In one exemplary embodiment, the rear electrode layer 100 may be formed by coating and drying an aluminum paste composition including an aluminum powder, a glass frit, and an organic vehicle through screen printing, and baking it at a temperature of more 660 Celsius (° C.) (the melting point of aluminum).

When executing this baking, the aluminum is diffused into the base layer 400 such that an aluminum (Al)-silicon (Si) alloy layer 140 is formed between the rear electrode layer 100 and the base layer 400, and a p+ layer 170 as an impurity layer by the diffusion of aluminum atoms is simultaneously formed.

The recombination of electrons may be prevented by the existence of the p+ layer 170 and a back surface field (“BSF”) effect for improving collecting efficiency of the generation carrier. The p+ layer 170 may be designated by a rear electric field layer.

A reflection prevention layer 600 is positioned directly on the upper surface of the emitter layer 500.

The reflection prevention layer 600 has a function of decreasing reflectance of the solar light incident to the light absorption layer of the solar cell.

The reflection prevention layer 600 may be a singular layer including one selected from a group consisting of a silicon nitride layer, a silicon nitride layer including hydrogen, a silicon oxidation layer, a silicon oxidation nitride layer and a combination thereof, or a multilayered structure including a combination including at least two layers thereof.

In exemplary embodiments, the reflection prevention layer 600 may be made by vacuum deposition, chemical vapor deposition, spin coating, screen printing, or spray coating.

The front electrode layer 700 is positioned directly on the emitter layer 500 and extends completely through a thickness of the reflection prevention layer 600, such that the front electrode layer 700 may be physically and/or electrically connected to the emitter layer 500.

The material property of the compound of the silicon nitride group forming the first passivation layer 200 in an exemplary embodiment of the invention is critical and important in realizing the high efficiency of the solar cell and to increase the reliability of the solar cell.

When forming the compound (SiNx) of the silicon nitride group of the first passivation layer 200, by using plasma-enhanced chemical vapor deposition (“PECVD”) or liquid phase chemical vapor deposition (“LPCVD”), the formation film conditions are controlled to provide a desired refractive index and absorption light coefficient.

In an exemplary embodiment of the invention, the first passivation layer 200 may be formed by using ammonia (NH₃) and silane (SiH₄) as a raw gas through the PECVD or LPCVD, and it is preferable that the refractive index of the silicon nitride group compound is equal to or less than about 1.96.

The raw gas may further include nitrogen (N₂).

Particularly, in an exemplary embodiment of the invention, the refractive index of the silicon nitride group compound may be in a range of about 1.8 to about 1.96.

As the refractive index of the silicon nitride group compound is decreased, improvement in characteristics of the solar cell is advantageous. However it is difficult to form the refractive index of the silicon nitride group compound at equal to or less than about 1.8 under a conventional process.

The ratio of the gas flow of ammonia (NH₃) and silane (SiH₄) used as the raw gas is controlled to form the first passivation layer 200 having the refractive index of the desired condition.

Particularly, to realize a refractive index equal to or less than about 1.96, the ratio of the gas flow of ammonia (NH₃) may be increased, and the ratio of the gas flow of silane (SiH₄) may be decreased.

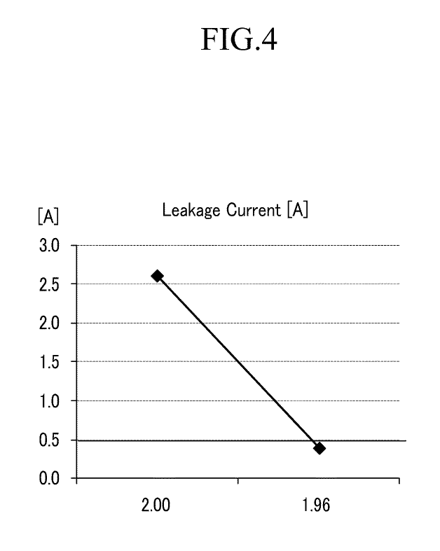

FIG. 3 is a graph showing a Fourier-Transform Infrared (“FT-IR”) analysis result for an Exemplary Example of a solar cell according to the invention and a Comparative Example.

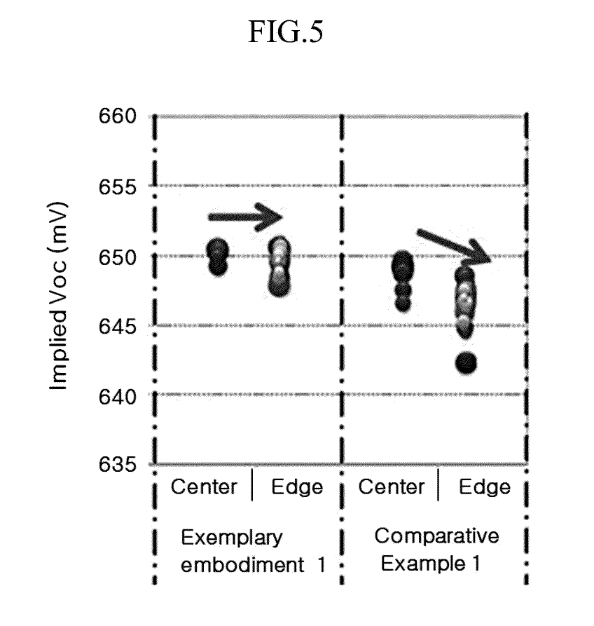

FIG. 4 is a graph showing leakage current of the Exemplary Example of a solar cell according to the invention and the Comparative Example.

In Table 1 below, the refractive index of the silicon nitride group compound forming the first passivation layer 200 is in the range of about 2.0 to about 2.1 in the Comparative Example, and the refractive index of the silicon nitride group compound forming the first passivation layer 200 is in the range of about 1.8 to about 1.96 in the

Experimental Example. In additional, the light absorption coefficient (K) of the Comparative Example is equal to or less than 0.03. However the light absorption coefficient (K) of the Experimental Example is equal to or less than 0.01, and an FT-IR analysis is executed.

TABLE 1

| | Comparative | Experimental |
|---|---|---|
| | Example | Example |
| Refractive index (633 nanometers | 2.0-2.1 | 1.8-1.96 |
| (nm)) | | |
| K (410 nanometers (nm)) | equal to or Less | equal to or Less |
| | than 0.03 | than 0.01 |
| Si—H bonds under FT-IR (2150 | Peak existence | No peak |
| reciprocal centimeter (cm−1)) | | |

Here, a deposition condition as in Table 2 below may be applied to obtain the refractive index of the silicon nitride group compound as in the Comparative Example and the Experimental Example.

TABLE 2

| | Refractive | |
|---|---|---|
| | index | Deposition condition |
| Comparative | 2.00 | 0.7Torr/2200 watts (W)/3000SiH₄— |
| Example | | 11,000NH₃—11,000N₂ |
| Experimental | 1.96 | 0.7Torr/2200 watts (W)/1000SiH₄— |
| Example | | 15,000NH₃—18,000N₂ |

To obtain the refractive index of the silicon nitride group compound as in the Comparative Example, the condition that the gas flow of silane (SiH₄) is 3000 standard cubic centimeters (sccm), the gas flow of ammonia (NH₃) is 11,000 sccm, and the gas flow of nitrogen (N₂) is 11,000 sccm is applied. To obtain the refractive index of the silicon nitride group compound as in the Experimental Example, the condition that the gas flow of silane (SiH₄) is 1000 sccm, the gas flow of ammonia (NH₃) is 15,000 sccm, and the gas flow of nitrogen (N₂) is 18,000 sccm.

The condition in which the pressure is 0.7 Torr and radio frequency (“RF”) power is 2200 W is commonly applied to both the Comparative Example and the Experimental Example.

Referring to FIG. 3, FIG. 4, and Table 1, the characteristics of the Experimental Example of the solar cell according to the invention may be compared with the Comparative Example of the solar cell.

Referring to FIG. 3, a peak having the wave number of 2150 reciprocal centimeter (cm-1) appears in the graph of the Comparative Example.

As the result of the FT-IR analysis, this means that a Si—H combination exists.

The peak of the Comparative Example graph having the wave number of 2150 cm-1, is not present in the graph of the Experimental Example.

This means that the ratio of Si—H for the passivation layer (e.g., the first passivation layer 200) is reduced in the Experimental Example.

When forming the first passivation layer 200 including the silicon nitride group compound through the PECVD or the LPCVD, when the content of Si—H is larger than that of Si—N, the characteristics of the solar cell are degraded.

That is, according to the Experimental Example of the solar cell according to the invention, the first passivation layer 200 has a refractive index of 1.8 to 1.96 and a light absorption coefficient (K) of less than 0.01, such that the content of Si—N may be increased and the content of Si—H may be reduced.

Accordingly, the characteristics of the solar cell may be improved.

Referring to FIG. 4, it may be confirmed that the leakage current of the Comparative Example (upper left -♦-) is 2.6 ampere (A), while the leakage current of the Experimental Example (lower right -♦-) is 0.4 ampere (A).

That is, in the exemplary embodiment (represented by the Experimental Example) of the invention, when the first passivation layer 200 is made of the silicon nitride group compound having the refractive index equal to or less than 1.96, the leakage current may be reduced.

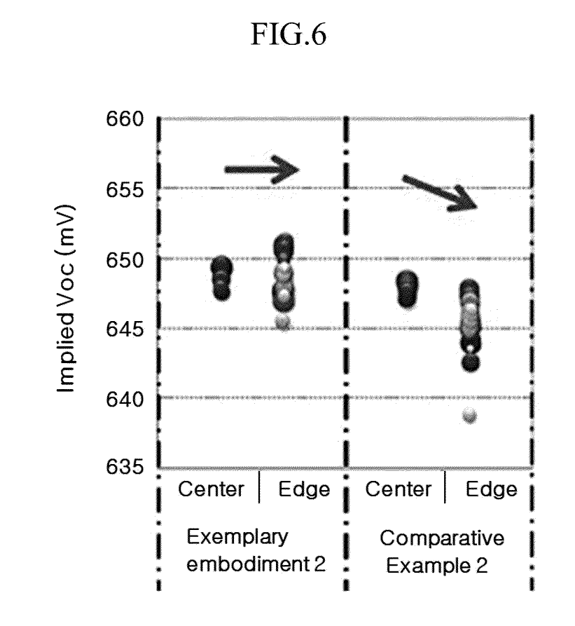

The effects related to the characteristics of an exemplary embodiment of a solar cell according to the invention, will be described with reference to FIG. 5 to FIG. 8.

FIG. 5 and FIG. 6 are graphs showing a measured open circuit voltage of exemplary embodiments of a solar cell according to the invention before forming an electrode, compared with Comparative Examples.

FIG. 5 is a graph showing an open circuit voltage (implied Voc) in millivolts (mV) at several positions of a center portion and an edge portion of a wafer in a diode state, before forming an electrode.

In general, it is necessary to consider that the characteristics of the solar cell are degraded by the influence of the impurity at the edge portion.

Referring to Exemplary embodiment 1 of a solar cell, the open circuit voltage (implied Voc) is close to 650 mV at the center portion. When the open circuit voltage is measured at the edge portion, the difference therebetween is small.

However, referring to Comparative Example 1 of the solar cell, it may be confirmed that the open circuit voltage (implied Voc) is decreased below 650 mV according to each of the measuring positions, and particularly, when measuring the edge portion, the difference therebetween is larger than that in the Exemplary embodiment 1.

FIG. 6 is the graph showing an open circuit voltage (implied Voc) at several positions of a center portion and an edge portion of a wafer in a diode state, before forming an electrode, like the case of FIG. 5.

Here, the heat treatment temperature used in manufacturing the solar cell is relatively high among the solar cell manufacturing processes, by considering a progress margin.

Referring to FIG. 6, in the case of measuring the open circuit voltage in the state securing the margin, it may be confirmed that the difference of the open circuit voltage is serious in Comparative Example 2, and the difference is generated less or not generated in Exemplary embodiment 2 compared with Comparative Example 2, and thereby the characteristics of a solar cell according to the invention are improved.

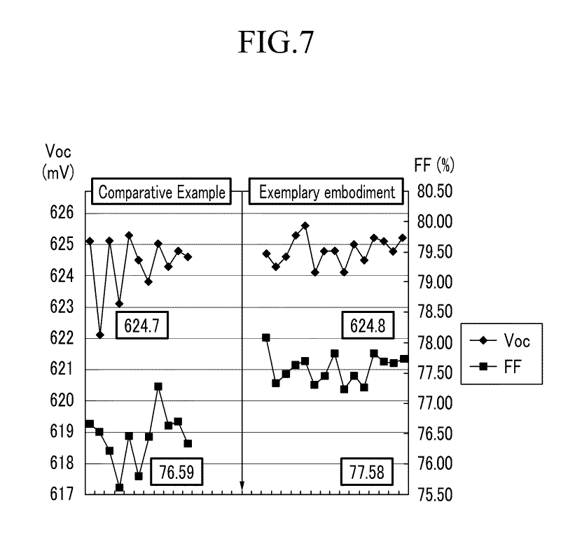

FIG. 7 is a graph showing a measured open circuit voltage and a fill factor of an Exemplary embodiment of the solar cell according to the invention after forming an electrode, compared with a solar cell of a Comparative Example.

It may be confirmed that the measured values of the open circuit voltage (e.g., -♦-) of the Comparative Example are widely distributed in the range of 622 mV to 625.4 mV, however the values of the open circuit voltage (e.g., -♦-) of the Exemplary embodiment are substantially uniformly distributed in the range of 624 mV to 625.8 mV.

Also, the values of the fill factor percentage (FF %) (e.g., -▪-) of the Comparative Example are distributed in the range of 77.5% to 75.50%, however the values of the fill factor percentage (e.g., -▪-) are distributed in the range of 77.25% to 78% in the Exemplary embodiment.

Accordingly, the range of the open circuit voltage and the fill factor of the Exemplary embodiment of the invention is high and stable, compared with the Comparative Example such that it may be confirmed that the characteristics of the solar cell according to the invention may be improved.

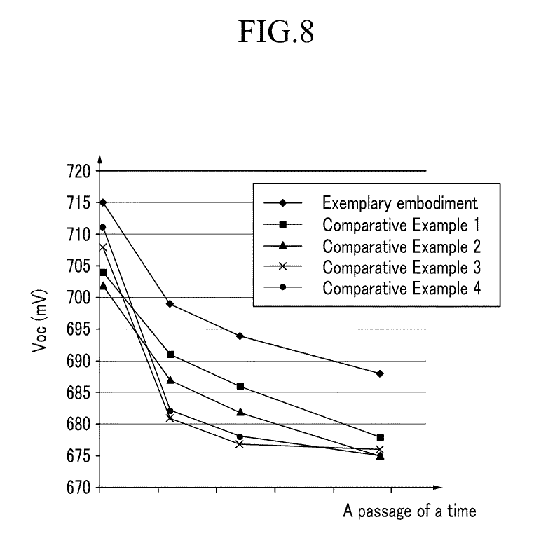

FIG. 8 is a graph showing a reliability of an Exemplary embodiment of a solar cell according to the invention, compared with solar cells of Comparative Examples.

Comparative Example 1 to Comparative Example 4 are cases where the open circuit voltage (Voc) is measured according to the passage of time when forming the first passivation layer made of the silicon nitride group compound having the refractive index of 2.0 to 2.1.

The Exemplary embodiment is a case where the open circuit voltage (Voc) is measured according to the passage of the time when forming the first passivation layer made of the silicon nitride group compound having the refractive of the range of 1.8 to 1.96, less than the Comparative Examples.

Referring to FIG. 8, in the Exemplary embodiment where the first passivation layer includes the silicon nitride group compound having the refractive index of 1.8 to 1.96 according to the invention, the open circuit voltage (Voc) decrease according to the passage of the time, is small compared with a decrease of the open circuit voltage (Voc) in the Comparative Example.

Accordingly, the solar cell according to an Exemplary embodiment of the invention may be improved in the aspect of reliability compared to the solar cell of the Comparative Examples.

An exemplary embodiment of method for manufacturing a solar cell shown in FIG. 1 according to the invention will now be described.

In the method, the “first passivation layer” and the “second passivation layer” respectively correspond to the second passivation layer 300 and the first passivation layer 200 described in the solar cell of FIG. 1.

The terms are amended considering the process sequence.

Firstly, the emitter layer 500 having the second conductive type of impurity is formed on a first surface of the silicon substrate (e.g., base layer 400) having the first conductive type of impurity. In one exemplary embodiment, the P-type silicon substrate of the base layer 400 is doped with the first conductive type of impurity element of IUPAC Group III (or Group 13) elements, such as boron (B), gallium (Ga), and indium (In). When the silicon substrate of the base layer 400 is a P-type, the emitter layer 500 is doped with the second conductive type of impurity element (e.g., N-type) of IUPAC Group V (or Group 15) elements, such as phosphorus (P), arsenic (As), and antimony (Sb).

When the emitter layer 500 is formed, the P—N junction is formed between the silicon substrate base layer 400 and the emitter layer 500.

The surfaces of the silicon substrate base layer 400 and the emitter layer 500 may be textured to form an uneven surface.

The uneven surface may increase the absorption amount of effective light into the solar cell.

The reflection prevention layer 600 is formed directly on the emitter layer 500.

The reflection prevention layer 600 has a function of decreasing reflectance of solar light incident to the light absorption layer of the solar cell.

The reflection prevention layer 600 may be a single layer including one selected from a group consisting of a silicon nitride layer, a silicon nitride layer including hydrogen, a silicon oxidation layer, a silicon oxidation nitride layer and a combination thereof, or a multilayered structure including a combination including at least two layers thereof.

Next, the first passivation layer (300 in FIG. 1) is formed on a second surface of the silicon substrate base layer 400 opposing the first surface.

The second passivation layer (300 in FIG.) may include aluminum oxide (Al₂O₃), and reflects the carriers generated by the photo-energy as a fixed charge to guide the carriers to the front electrode 700.

Next, the second passivation layer (200 in FIG. 1) including the silicon nitride group compound is formed on the first passivation layer (300 in FIG. 1).

The second passivation layer (200 in FIG. 1) may be formed by using PECVD.

The raw gas used in forming the second passivation layer (200 in FIG. 1) may be ammonia (NH₃), silane (SiH₄), and nitrogen (N₂) in the process using PECVD.

According to an exemplary embodiment of the invention, the gas flow of the raw gas is controlled such that the second passivation layer (200 in FIG. 1) has a refractive index equal to or less than 1.96, and particularly in the range of 1.8 to 1.96.

The rear electrode 100 is formed on the second passivation layer (200 in FIG. 1), such as by using a screen printing method.

Next, heat treatment may be executed on the formed structure.

Likewise, the front electrode 700 is formed on the reflection prevention layer 600 by using the screen printing method, and then may be heat-treated.

The front electrode 700 and the rear electrode 100 may be simultaneously formed.

If the heat treatment is executed, the front electrode 700 material is passed through the reflection prevention layer 600 by a punch-through phenomenon and is physically and/or electrically connected to the emitter layer 500.

Also, the rear electrode 100 material is diffused through a rear (e.g., second) surface of the silicon substrate base layer 400, such that a rear surface field layer is formed in the interface of the rear electrode 100 and the silicon substrate base layer 400, and thereby reducing or effectively preventing the carriers from being moved to the rear surface of the silicon substrate base layer 400 and recombined.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A solar cell comprising:
a base layer including a first conductive type impurity element from a first Group of elements, an upper surface, and a lower surface opposing the upper surface;
an emitter layer on the upper surface of the base layer and including a second conductive type impurity element from a second Group of elements different from the first Group;
a front electrode connected to the emitter layer;
a first passivation layer on the lower surface of the base layer; and
a rear electrode on the first passivation layer and connected to the base layer,
wherein the first passivation layer includes a silicon nitride group compound, and a refractive index of the silicon nitride group compound is equal to or less than about 1.96.

2. The solar cell of claim 1, wherein
the refractive index of the silicon nitride group compound is in a range of about 1.8 to about 1.96.

3. The solar cell of claim 2, wherein
a light absorption coefficient of the first passivation layer is equal to or less than about 0.01.

4. The solar cell of claim 3, further comprising
a second passivation layer between the lower surface of the base layer and the first passivation layer.

5. The solar cell of claim 4, wherein
the second passivation layer includes of aluminum oxide.

6. The solar cell of claim 5, further comprising
a reflection prevention layer on the emitter layer.

7. The solar cell of claim 6, wherein
the front electrode is extended through the reflection prevention layer, and is connected to the emitter layer.

8. The solar cell of claim 1, wherein
a portion of the rear electrode is extended through the first passivation layer, and is connected to the base layer.

9. The solar cell of claim 8, further comprising
a rear electric field layer on the lower surface of the base layer, the first passivation layer being between the rear electric field layer and the base layer.

10. The solar cell of claim 1, wherein the first Group and the second Group are selected from International Union of Pure and Applied Chemistry Groups III and V elements.

11. A method manufacturing a solar cell, the method comprising:
forming a base layer including a first conductive type impurity element from a first Group of elements, an upper surface, and a lower surface opposing the upper surface;
forming an emitter layer on the upper surface of the base layer, and including a second conductive type impurity element from a second Group of elements opposing the first Group of elements;
forming a first passivation layer on the lower surface of the base layer;
forming a second passivation layer on the first passivation layer; and
forming a front electrode connected to the emitter layer, and a rear electrode on the second passivation layer and connected to the base layer,
wherein the second passivation layer includes a silicon nitride group compound, and a refractive index of the silicon nitride group compound is equal to or less than about 1.96.

12. The method of claim 11, wherein
the refractive index of the silicon nitride group compound is in a range of about 1.8 to about 1.96.

13. The method of claim 12, wherein
a light absorption coefficient of the second passivation layer is equal to or less than about 0.01.

14. The method of claim 13, further comprising
forming a reflection prevention layer on the emitter layer.

15. The method of claim 14, wherein
the first passivation layer is formed of aluminum oxide.

16. The method of claim 11, wherein
the forming a second passivation layer includes plasma-enhanced chemical vapor deposition.

17. The method of claim 11, wherein
the forming a second passivation layer includes forming the silicon nitride group compound by using a raw gas including silane or ammonia.

18. The method of claim 17, wherein
the raw gas for the formation of the silicon nitride group compound further includes nitrogen.

19. The method of claim 18, wherein
the forming a second passivation layer includes a process condition that gas flows of the silane, the ammonia, and the nitrogen are respectively 1000 standard cubic centimeters, 15,000 standard cubic centimeters, and 18,000 standard cubic centimeters.
